(19) United States
(12) Patent Application Publication
(10) Pub. No.: US 2003/0156703 A1
(43) Pub. Date: Aug. 21, 2003

(54) Method and device for the establishment of a telephone connection

(76) Inventor: Siegmund Kocma, Wiesenttal (DE)

Correspondence Address: SIEMENS SCHWEIZ, I-44, INTELLECTUAL PROPERTY, ALBISRIEDERSTRASSE 245, ZURICH, CH-8047, CH

(21) Appl. No.: 10/347,436

(22) Filed: Jan. 21, 2003

(30) Foreign Application Priority Data
Jan. 29, 2002 (DE) 10203368.4

(51) Int. Cl. G01R 31/08; G06F 11/00; H04J 3/14; H04J 1/16; H04L 1/00; H04M 5/00; H04M 3/00; G08C 15/00; H04L 12/26

(52) U.S. Cl. 379/242; 370/252

(57) ABSTRACT

The invention concerns a method and a device for the establishment of a telephone connection between a first operator (10 at a technical installation (1) and a second person (17) supporting the first person (10) by telephone. To establish the telephone connection, the first person (10) contacts a first computer (11) with a first telephone (5) and transmits it an identification (MR1245_T10) assigned to the workings at the technical installation (1). Thereupon, the first computer (11) determines, based on information which is stored in a list (13a) assigned to the identification (MR1245_T10), the telephone number of a second telephone (17a) assigned to a second person (17) and establishes the telephone connection between the first and the second telephone.

### CROSS REFERENCE TO RELATED APPLICATIONS

The present application claims priority to German patent application number 10203368.4, filed Jan. 29, 2002, which is herein incorporated by reference.

### STATEMENT REGARDING FEDERALLY SPONSORED RESEARCH OR DEVELOPMENT

Not applicable.

### REFERENCE TO SEQUENCE LISTING, A TABLE, OR A COMPUTER PROGRAM LISTING COMPACT DISK APPENDIX

Not applicable.

### BACKGROUND OF THE INVENTION

The invention concerns a method and a device for the establishment of a telephone connection between an operator at a technical installation and an assistant to the operator.

A technical installation such as a transporting plant or a technical installation as for example a medico-technical device, are particularly understood by a technical installation. A carried out servicing, a carried out maintenance, an initial operation or operations concerning a fault clearance of the technical installation are particularly understood by operations at a technical installation.

Sometimes an operator working at a technical installation, as for example a technician requires additional, for the execution of the assignments necessary information regarding the technical installation, which is not available at the location of the technical installation. Such information is for example technical data, data regarding settings or tests to be carried out regarding the technical installation. Without knowledge of this information, it is more difficult or impossible for the technician to continue or finish the assignments. To continue the assignments at the technical installation, the technician can for example contact an expert of the manufacturer of the technical installation with a telephone, so that he assists the technician with the continuation of the operations by telephone. The expert is therefore a qualified person to assist the technician by telephone. Especially if a manufacturer sells many heterogeneous technical installations, it can be complicated for the technician to reach telephonically a qualified expert for the technical installation he is working on.

The task of the invention is therefore, to indicate a method, with which assistance a telephone connection between the technician and the expert is established as fast and as convenient as possible for the technician. A further task of the invention is to develop a device in such a way, that a telephone connection between the technician and the expert can be made as fast as possible with the device's assistance.

The first task is solved by a method for the establishment of a telephone connection, showing the following procedure steps:

Contact by a communication network of a first computer with a telephone, which is assigned to an operator working at a technical installation and to which a first telephone number is assigned,

Reception of a identification allocated to the assignments at the technical installation by the first computer,

Determination, based on the identification and based on a list assigned to the identification of information stored on a first database accessible by the first computer, of a second telephone number of a second telephone, which is assigned to a second person, who should assist the first person with the execution of the assignments, and

Establishment of a telephone connection between the first telephone and the second telephone.

The method according to the invention enables the technician who carries out the assignments at the technical installation and requires the technical assistance, to receive, in a relatively simple manner, a telephone connection with the expert who assists him. The technician only needs to contact the first computer with the first telephone and to transmit the identification allocated to the assignments. The identification allocated to the assignments is for example an interference or order number, which was allocated based on an order for the execution of assignments, for example because of an interference message regarding the technical installation before the initiation of the assignments. Based on this identification, which allows a clear identification of the assignments, the second telephone number assigned to the expert is, in particular, automatically determined according to the invention and the telephone connection between the first and the second telephone is made. According to the invention, the second telephone number, therefore the telephone number of the telephone, which is assigned to the expert for the assistance of the technician, is determined based on the list assigned to the identification of the first database. This list can for example be generated automatically, as soon as the identification assigned to the operations has been allocated. This list includes consequently information, which allows reaching conclusions regarding a qualified expert for the assistance of the technician. An advantage of the method according to the invention is for example that the technician needs to contact with the first telephone only the first computer and to enter the identification allocated to the assignments. The telephone connection with the qualified expert is then established automatically. The technician therefore only needs to dial one single telephone number, namely the telephone number, with which he contacts the first computer. In addition, telephones are usually easily accessible at the location of the technical installation, be it, that the technician has a portable phone available or that a telephone connected to the fixed network is located near the technical installation, so that the technician receives assistance by telephone in a relatively short time, to continue efficiently the assignments at the technical installation.

The identification allocated to the assignments at the technical installation can be transmitted to the first computer, according to a design of the invention, with a keypad of the first telephone.

But the telephone connection can be established in a particularly convenient way for the technician, if, according to an especially preferred variant of the invention, the first computer comprises means for speech analysis, so that the identification allocated to the assignments at the technical installation is transmitted orally by the first telephone and the first computer processes the orally transmitted identification.

According to a further variant of the invention, it is provided, that the information stored in the list of the first database contains information regarding the type of the technical installation, where the assignments are carried out, and based on the type of the technical installation, the second telephone number of the second telephone is determined. With this, it is assured, that the operator carrying out the assignments at the technical installation is connected to a particularly qualified expert.

According to a further design of the invention, it is provided, that the information stored in the list of the first database contains information regarding the second telephone number of the second telephone, if the first computer has already made a telephone connection at an earlier time between the fist telephone and the second telephone. The technician is therefore connected to the same expert, should he require assistance again. This expert is then already familiar with the assignments at this special technical installation and is thus able to assist the technician quicker than if the technician telephones each time to a different expert.

According to a particularly preferred variant of the invention, it is provided, that the following procedure step is carried out after the establishment of the telephone connection between the first telephone and the second telephone:

Registering of information regarding a third telephone number of a third telephone into the list of the first database assigned to the identification, whereby the third telephone is assigned to a third person higher who is ranking than the second person.

Based on the registration of the information regarding the third telephone number, according to a further variant of the invention, a telephone connection between the first telephone and the third telephone is established in place of a telephone connection between the first telephone and the second telephone. Should the technician particularly require repeated assistance and be concluded, that the expert, to whom the second telephone is assigned, cannot assist the technician in the requested way, the information regarding the third telephone number is then registered into the list according to the invention, so that the technician is connected automatically with the third person who is higher ranking than the second person, as soon as the technician contacts again the first computer. The third person is for example an additional expert familiar with the technical installation. This procedure is then particularly advantageous, when the manufacturer makes experts available to the technician for example on a regional and national level, but primarily contacts the experts on the regional level and the experts nationwide are only contacted in special cases, if for example the regional experts cannot sufficiently assist the technician on-site.

According to an additional, particularly preferred variant of the invention, it is provided, that the following procedure steps are additionally carried out:

Contacting by the first computer of a second database, where a data record assigned to the technical installation is stored,

Calling up of the data record assigned to the technical installation, and

Transmitting of the requested data record to a second computer assigned to the second telephone.

The second person, thus the expert assisting the technician, therefore receives conveniently information regarding the technical installation, where the technician is operating. By this, the expert can assist the technician quicker and more efficiently.

The second task of the invention is solved by a device for the establishment of a telephone connection, showing:

a first database, where a list assigned to an identification is stored, whereby the identification is assigned to the operations at a technical installation, and

a first computer, which is connectable to the first database and to a communication network, which is designed in such a way, that it

can be contacted from a first telephone by the communication network, whereby the first telephone is assigned to a first operator at the technical installation and a first telephone number,

based on the identification received from the first telephone and from information of the list assigned to the identification of the first database, a second telephone number of a second telephone, which is assigned to a second person, can be determined, and

a telephone connection between the first telephone and the second telephone can be established.

The device according to the invention comprises thus the first database and the first computer connected to the first database. The list assigned to the identification is stored in the database. The identification is assigned to the operations at the technical installation and is for example an interference or order number, which, based on a order for the execution of assignments, for example because of an interference message, was, regarding the technical installation, allocated before the initiation of the assignments. This list contains additional information, with which assistance the first computer, after it has been contacted and been communicated the identification, can determine that telephone number, which is assigned to the second telephone, after which the first computer can establish the telephone connection between the first and second telephone. The device according to the invention is designed in such a way, that the method according to the invention can be implemented with it. Further designs and advantages result from the sub-claims.

### BRIEF DESCRIPTION OF THE SEVERAL VIEWS OF THE DRAWINGS

The novel features and method steps believed characteristic of the invention are set out in the claims below. The invention itself, however, as well as other features and advantages thereof, are best understood by reference to the detailed description, which follows, when read in conjunction with the accompanying drawing, wherein:

FIG. 1 a scenario pictorializing the method according to the invention and the device according to the invention,

FIGS. 2 to 4 different stages of information of a list of assignments associated to a technical installation.

### DETAILED DESCRIPTION OF THE INVENTION

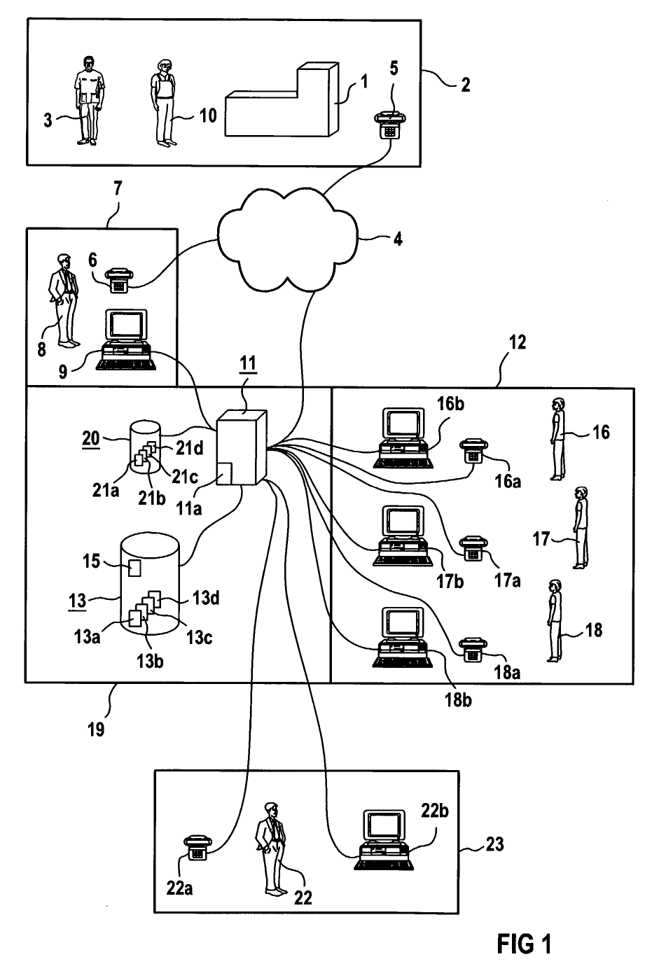

FIG. 1 shows a magnetic resonance device 1, which is located in a physician's practice 2 of a physician 3. In the case of the present example of design, the magnetic resonance device 1 was sold from a manufacturer of different medico-technical devices to a physician 3. The manufacturer offers also computer topography devices, lithotripters and x-ray devices not disclosed in FIG. 1, apart from the magnetic resonance devices.

In the case of the present example of design, the magnetic resonance device 1 is defective. The physician 3 therefore contacts with his telephone 5 connected to a communication network 4, a telephone 6 connected to a communication network 4 of the manufacturer of the magnetic resonance devices 1, which is located in a call center 7 of the manufacturer. The call center 7 is destined for that region, where the physician 3 has his physician's practice. The region is in the case of the present example of design a country A. An employee 8 of the manufacturer of magnetic resonance devices 1 works in the call center 7, who receives the call of the physician 3.

Based on the interference message of the magnetic resonance device 1, the employee 8 sends a technician 10 to the physician 3, so that he repairs the magnetic resonance device 1.

Before the employee 8 sends the technician 10 to the physician's practice 2, to repair the magnetic resonance device 1, thus to carry out workings at the magnetic resonance device 1, he allocates an order number assigned to the repair of the magnetic resonance device 1. In the case of the present design of execution, the employee 8 has furthermore access to a computer 9, which is connected to a central computer 11, which is located in the computer room 12 of the manufacturer of the magnetic resonance devices 1. The central computer 11 is connected again with a database 13, where lists are stored, which are assigned to the delivered devices by the manufacturer in the country A, and where operations are being carried out right now. An order number is again allocated to each of these assignments, with which the list assigned to the respective operations can be clearly identified. The lists show also information regarding the corresponding device apart from the order number assigned to them.

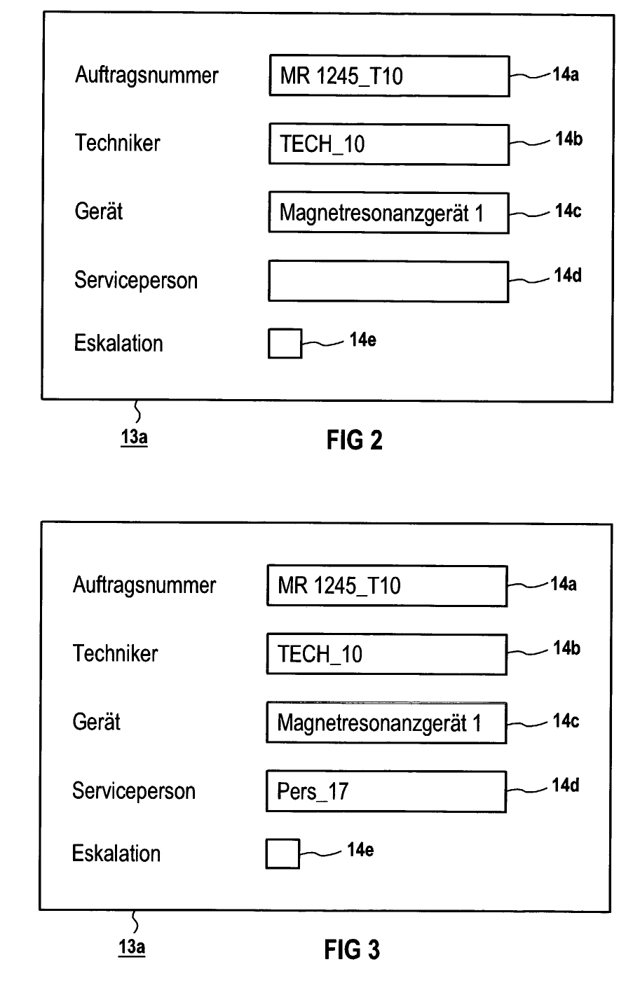

In the case of the present example of design, the employee 8, after he has allocated the order number, which is assigned to the workings at the magnetic resonance device 1, sets up a list 13a in the database 13 by the computer 9. Additional, in the FIG. 1 disclosed lists 13b to 13d, are assigned to additional, already allocated order numbers. The list 13a is additionally further disclosed in FIG. 2.

The list 13a comprises, in the case of the present example of design, fields 14a to 14e. The employee 8 enters the order number into field 14a, which is in this case “MR1245_T₁₀”. The field 14b is intended for an identification of the technician 10, that's why the employee 8 enters the personnel number of the technician 10 into the field 14b. The personnel number in this case of the present example of design is “TECH_{—}10”. The employee 8 annotates in the field 14c, that the workings concern assignments at the magnetic resonance device 1. The fields 14d and 14e remain blank until later and are further explained in more detail below. The fields 14a to 14c of the list 13a are disclosed completed in FIG. 2.

During the repair of the magnetic resonance device 1, thus during the carried out operations at the magnetic resonance device 1, the technician 10 meets a problem, which he can not solve without further information regarding the magnetic resonance device 1. He therefore contacts the central computer 11 of the manufacturer of the magnetic resonance device 1 with the telephone 5 located in the physician's practice 2. The central computer 11 comprises, in the case of the present example of design, means for speech reproduction and speech analysis 11a generally known to the expert, which are designed in such a way, that it asks a person contacting the central computer 11, in the case of the present example of design, thus the technician 10, for his identity and for an order number assigned to the workings at a device of the manufacturer.

Following this, the technician 10 communicates to the central computer 11 his personnel number and order number “MR1245_T10”, which are assigned to the workings at the magnetic resonance device 1. Based on the means for speech reproduction and speech analysis 11a, the central computer 11 interprets with an apt computer program the transmitted information of the technician 10 and calls up the list 13a in the database 13a assigned to the order number “MR1245_T₁₀”.

Based on the information stored in the list 13a, the running computer program on the central computer 11 recognizes that the technician 10 works at the magnetic resonance device 1. This information is filed in the field 14c of the list 13a.

Furthermore, a list 15 is stored in the database 13, where telephone numbers of persons are filed, who work for the manufacturer and are intended, if necessary, to assist by telephone the workings of the technicians, who carry out local assignments at a device of the manufacturer in country A. These persons work in a regional service center 19 of country A. In addition, the list 15 contains information of which person has apt qualifications to assist a technician working on-site for the respective device offered by the manufacturer. In the case of the present example of execution, exemplary persons 16, 17 and 18 are disclosed in FIG. 1, who each has is qualified in the area of magnetic resonance. A telephone 16a, 17a resp. 18a and a PC 16b, 17b resp. 18b connected to the central computer 11 are assigned to the persons 16 to 18. Besides, the manufacturer of the magnetic resonance device 1 employs also persons with professional knowledge of computer tomography device, lithotripters and x-ray-devices manufactured by him. These persons are not disclosed in FIG. 1.

The central computer 11 can therefore, based on the information stored in the list 13a and the list 15, determine, if the persons 16 to 18 are qualified to assist the technician 10. In the following, the central computer 11 tries to connect the telephone 5 of the physician's practice 2 with one of the telephones 16a to 18a, by first trying to establish a telephone connection with the telephone 16a. This telephone connection cannot be established, because in the case of the present example of execution, the telephone is busy, because the person 16 is talking on the phone to another technician right now not disclosed in FIG. 1. Thereupon, the central computer 11 tries to establish a telephone connection with the telephone 17a of the person 17. Person 17 is available and the telephone 17b is free, so that the telephone connection between the telephone 17b of the person 17 and the telephone 5 of the technician 10 can be established.

After the establishment of the telephone connection, the central computer 11 fills out the field 14d of the list 13a automatically with an identification assigned to person 17, which in the case of the present example of design is “Pers_{—}17”, so that the establishment of the telephone connection with the telephone 17a of the person 17 is documented. This is disclosed in FIG. 3.

The central computer 11 is in the case of the present example of design additionally connected to an additional database 20, where detailed information regarding the devices delivered by the manufacturer, is stored. This information is filed on lists assigned to the individual devices, of which exemplary lists 21a to 21d are shown in FIG. 1. These lists comprise among others, general technical data of the respective devices and specific information assigned to the special device, as for example, maintenance protocols, information regarding the configuration, etc . . . . In the case of the present example of design, the lists 21a are assigned to the magnetic resonance device 1.

Because the central computer 11 has already detected, that the technician 10 works at the magnetic resonance device, it calls up the list 21a assigned to the magnetic resonance device 1 from the database 20 and transmits the information assigned to the list 21a to the computer 17b of the person 17. The person therefore receives automatically important information on the screen of his computer 17b, so that he can effectively support the technician 10 with the assignment at the magnetic resonance device 1.

After the person 17 having finished assisting the technician 10 in an adequate way, the technician 10 continues the workings at the magnetic resonance device 1. But after a while he meets again with a problem, so that he contacts again the central computer 11 with the telephone 5 and transmits to it the order number “MR1245_T10” assigned to the workings at the magnetic resonance device 1. Following this the central computer 11 calls again the list 13a assigned to the order number “MR1245_T10” and disclosed in FIG. 3. At this time the list 13a contains already information that the person 17 has already assisted to the technician 10 at the current operations at the magnetic resonance device 1, so that the central computer 11 tries immediately to establish a telephone connection between the telephone 5 and the telephone 17a of the person 17.

After the establishment of the telephone connection between the telephone 5 and the telephone 17a, the central computer 11 automatically calls again the list 21 of the database 10 assigned to the magnetic resonance device 1 and transmits the data of the list 21a to the computer 17b of the person 17.

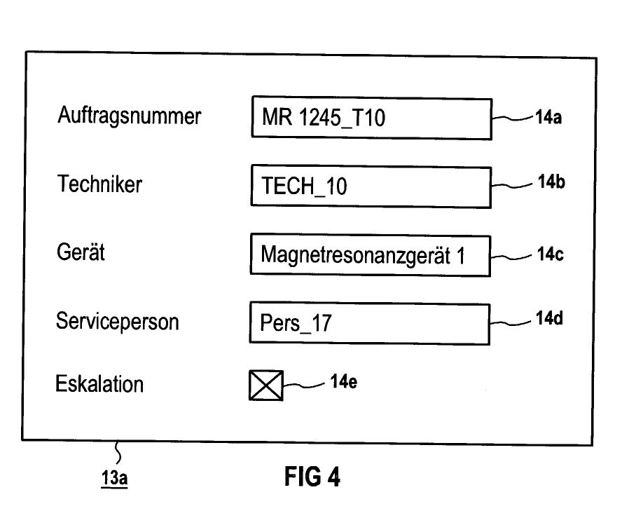

During the conversation between the technician 10 and the person 17, it turns out that person 17 reached his limits regarding his professional knowledge. He therefore connects the technician 10 with a higher ranking person 22, who, in the case of the present example of design, works in national service center 23. A telephone 22a and a computer 22b are assigned to the person 22. The telephone connection between the telephone 5 of the technician 10 and the telephone 22a of the person 22 is established by the central computer 11. Based on the establishment of the telephone connection, the central computer 11 calls up the list 13a stored in the database 13 and marks the field 14a, disclosed in FIG. 3 and described with the word “escalation”; the list 13a is shown with the marked field 14a in FIG. 4. The reason for the automatic marking is that the technician 10, based on the marked field 14e of the list 13a, doesn't make a telephone connection between the telephone 5 of the technician 10 and the telephone 17a of the person 17, but immediately makes a telephone connection between the telephone 5 and the telephone 22a with the person 22 working in the national service center 23. At a repeated inquiry of the technician 10, the central computer 11 also transmits automatically the data assigned to the magnetic resonance device 1 and stored in list 21a to the computer 22b of the person 22.

The above described example of design comprises medico-technical devices. The method according to the invention, resp. the device according to the invention can also be used for other devices and generally for technical installation.

The central computer 11 doesn't have to necessarily comprise means for the speech reproduction and speech analysis 11a. The identification assigned to the workings at the magnetic resonance device 1 can also be transmitted by the keypad of the telephone 5. The telephone 5 does also not need to be a fixed network telephone; it can also be a portable telephone.

The invention being thus described, it will be obvious that the same may be varied in many ways. The variations are not to be regarded as a departure from the spirit and scope of the invention, and all such modifications as would be obvious to one skilled in the art are intended to be included within the scope of the following claims.

I claim:

1. A method for the establishment of a telephone connection showing the following procedure steps:
Contacting of a first computer (11) by a communication network (4) with a first telephone (5), which is assigned to an operator at a technical installation (1) and to which a first telephone number is assigned,
Receiving of an identification (MR1245_T10) assigned to the operations at the technical installation (1) by the first computer (11),
Determining of a second telephone number of a second telephone (17a), which is assigned to a second person (17), who is supposed to assist the first person (10) at the execution of the assignments, based on the identification (MR1245_T10) and based on the list (13a) assigned to an identification of information stored in a first database (13) accessible by the first computer (11), and
Establishing of a telephone connection between the first telephone (5) and the second telephone (17b).

2. The method according to claim 1, at which the identification (MR1245_T10) assigned to the workings at the technical installation (1) is transmitted to a first computer (11) by a keypad of a first telephone (5).

3. The method according to claim 1, at which the first computer comprises means for the speech analysis (11a), so that the workings at the identification (MR₁₂₄₅_T10) assigned to the technical installation (1) is orally transmitted from the first telephone (5)) and the first computer (11) processes the orally transmitted identification (MR1245_T10).

4. The method according to one of the claim, at which the information stored in the list (13a) of the first database (13) contains information regarding the type of the technical installation (1), where the workings are carried out, and based on the type of the technical installation (1), the second telephone number of the second telephone (17b) is determined.

5. The method according to one of the claim 1, at which the information stored in the list (13a) of a first database (13), contains information (14d) regarding the second telephone number of the second telephone (17b), if the first computer (11) already established a previous telephone connection between the first telephone (5) and the second telephone.

6. The method according to one of the claim 1, which comprises, after the establishment of the telephone connection between the first telephone and the second telephone (17b), the following procedure steps:
Registering of information (14e) by a third telephone number of a third telephone (22b) into the list (13a) assigned to the identification (MR1245_T10) of a first database (13), whereby the third telephone (22b) is assigned to a third person (22), higher ranking than the second person.

7. The method according to claim 6, where, based on the information regarding the third telephone number and in place of a telephone connection between the first telephone (5) and the second telephone (17b), a telephone connection between the first telephone (5) and the third telephone (22b) is established.

8. The method according to one of the claim 7, which additionally comprises the following procedure steps:
Contacting of a second database (20), where a data record (21a) assigned to the technical installation (1) is stored, by the first computer (11),
Calling up of the data record (21a) assigned to the technical installation (1), and
Transmitting of the called up data record (21a) to a second computer (17c) assigned to the second telephone (17b).

9. A device for the establishment of a telephone connection, showing
a first database (13, where a list (13a) assigned to an identification (MR1245_T10) is stored, whereby the identification (MR1245_T10) is assigned to workings at a technical installation (1) and
a first computer (11), connectable to a first database (13) and to a communication network (4), which is designed in such a way, that it
can be contacted by the communication network (4) from a first telephone, whereby the first telephone (5) is assigned to a first operator (10) at the technical installation (1) and to a first telephone number,
a second telephone number of a second telephone (17a), which is assigned to a second person (17), can be determined, based on the received identification (MR1245_T10) by the first telephone (5) and from information of the list (13a) assigned to the identification (MR1245_T10) of a first database (13), and
a telephone connection between the first telephone (5) and the second telephone (17a) can be established.

10. The device according to claim 9, where the first computer (11) is designed in such a way, that the identification (MR1245_T10) is transmittable by a keypad of the first telephone (5).

11. The device according to claim 9, where the first computer (11) comprises means for speech analysis (11a), so that it processes an orally transmitted, by the first telephone (5), identification (MR1245_T10).

12. The device according to one of the claim 9, where the information stored in the list (13a) of the first database (13) contains information regarding the type of the technical installation (1), where the operations are carried out, and based on the type of the technical installation (1), the second telephone number of the second telephone (17a) can be determined.

13. The device according to one of the claim 9, where the information stored in the list (13a) of the first database (11) contains information regarding the second telephone number of the second telephone (17a), if the first computer (11) already established a telephone connection at an earlier time between the first telephone (5) and the second telephone (17a).

14. The device according to one of the claim 9, which additionally comprises a second database (20) contactable by the first computer (11), where a data record (21a) assigned to the technical installation (1) is stored, and the first computer (11) is designed in such a way, that it calls up the data record (21a) assigned to the technical installation (1) and transmits it to a second computer (17b) assigned to a second telephone (17a).
